(19) United States
(12) Patent Application Publication
(10) Pub. No.: US 2008/0000682 A1
(43) Pub. Date: Jan. 3, 2008

(54) Shielded Enclosure for Electromagnetic Fields

(75) Inventor: Enrique Armillas Daunert, Cornella de Llobregat (ES)

Correspondence Address: PEARNE & GORDON LLP, 1801 EAST 9TH STREET, SUITE 1200, CLEVELAND, OH, 44114-3108, US

(73) Assignee: ADVANCED SHIELDING TECHNOLOGIES EUROPE S.L., Cornella de Llobregat (ES)

(21) Appl. No.: 11/572,739

(22) PCT Filed: Jul. 27, 2004
(86) PCT No.: PCT/IB04/51296

§ 371 Date: Jan. 26, 2007

(51) Int. Cl. H05K 9/00

(52) U.S. Cl. 174/377

(57) ABSTRACT

The present invention relates to a smart shelter providing a flexible, quick and efficient solution to companies and private persons having a growing concern regarding their data network security/control. The smart shelter is a reliable solution, it can be fitted easily and rapidly and it is able to comply with major requirements providing protection/prevention against the majority of the above mentioned risk factors. In comparison with other more conventional systems of building data storage facilities, the smart shelter provides the following advantages: 1) electromagnetic protection against electrical fields, 2) electromagnetic protection against magnetic fields, 3) modular structure having excellent behavior against fire (RF120) and integrity against smoke and water (IP67). Its major advantages are: 1) a smart shelter has been designed specifically for data storage facilities, 2) it is a perfectly designed solution integrating all the above mentioned features, 3) it has already been implemented successfully in the past in other facilities, 4) it is a fully integrated facility delivered turnkey, 5) the project management has been given to and completed by highly qualified staff, 6) one only person is in charge of the whole project, 7) the certificate of conformity complies with the application standards.

I. Technical Field:

‘SMART SHELTER’ is the application relating to data storage rooms (I.T. Rooms).

II. Background:

‘SMART SHELTER’ originated to provide a flexible, quick and effective solution to companies and individuals given the grown concern for the security/control of their data networks. According to various studies, it has been demonstrated that 90% of the companies that lose all their data go bankrupt in less than 12 months (source HP, Swiss Re, ...).

The principal risk factors in a DPC are the following:
Natural:
Flood
Fire
Heat
Storms
Earthquakes
Human:
Electromagnetic Fields (transformation centres, power distribution trays, ...)
Power Outages
Vandalism
Unintentional Human Error
Sabotage/Terrorism
Data Networks:
Network Saturation (IP conflicts, ...)
Hackers and Virus

The ‘SMART SHELTER’ is a reliable solution of easy and quick installation that is capable of responding to the greatest demands, offering protection/prevention against the majority of the risk factors listed above.

III. Description of the Invention: ‘SMART SHELTER’

In comparison with other more traditional systems of constructing data storage rooms, the ‘SMART SHELTER’ presents the following advantages:

1. Electromagnetic Protection for Electric Fields:

Thanks to its exclusive protection, the ‘SMART SHELTER’ permits reducing to levels of around 10 dB the electrical fields of direct exposure. As an example, a traditional data storage room, located 6 m from an electrical field source (in this case a broadcasting antenna operating at 0.9 GHz) would receive a maximum exposure of around 10 V/m; on the contrary with the shielding technology of the ‘SMART SHELTER’, the maximum electrical field incidence would not be over 3.5 V/m. The ‘SMART SHELTER’ is effective for any electrical field source, independently of its power and/or frequency and independently also of the proximity of the source.

a) Description and Characteristics:

As can be seen in the following theoretical EXPOSITION, the intensity of the field (V/m) mostly depends on the power and frequency of the emitting source. (See AST-formula 1).

FORMULA 1
WDᵣ =(W_{T}G_{T})/4 r²
Where:
WDᵣ: Density of power in the point of study (W/m²)
W_{T}: Power of the broadcasting antenna (W)
G_{T}: Gain in the broadcasting antenna
r: distance (m)
E² =WDᵣ²Z₀
Where:
E: Electrical field in the point of study (V/m)
Z₀: Impedance of the air (120 )

The shielding of the ‘SMART SHELTER’ is based on the principle of reflection of electrical fields. This principle states that the more conductive a surface is, the more it will reflect a radio wave falling on it; and therefore, it will reduce the level of the electrical field.

If the surface is partially covered by a shield of conductive materials (i.e., Copper, Nickel, Silver...) there will be a certain lessening of the electrical field.

The more extensive, complete, uniform, dense and closed (to avoid the entrance of electrical field waves) is this shield, the greater shall be the level of reduction achieved (see the attached figure).

a) Princinal Advantages of the Reduction of the Electrical Field Levels:

1. Equipment: It creates a more favourable setting for the electronic and computer equipment and machines exposed directly to this field, since in many cases it reduces and adapts the electrical field levels in the atmosphere to the maximum levels of immunity required by the international guidelines of Electromagnetic Compatibility (i.e., EEC/89/336, ...) and specifically international standards of immunity to Electrical Fields (i.e., IEC/EN 610004-3), guaranteeing in this way the perfect functioning of this equipment against the proximity of such a source of emission.

2. Persons: It reduces the exposure level of the Electrical Field of persons, so that they adapt to the levels that can be found in an open field, with the consequent psychological benefit for the persons exposed and also the possible physical benefit, according to different medical studies.

1. Electromagnetic Protection for Magnetic Fields:

Thanks to its exclusive protection, the ‘SMART SHELTER’ permits reducing to levels less than 37.5 mG according to the European standard IEC/EN 6100-4-8. In addition to this standard, there are many studies that recommend lower field levels (NCRM 10 mG; MPRII 2.5 mG, ...).

The criterion of AST is to adopt the 10 mG as the security limit for persons and equipment.

The principal magnetic field sources are usually related to the transmission of electrical power; these sources are:
Transformer Centres
Electrical power switches
Power cables
Other equipment:
High-powered air conditioners
SAI's
Generating Systems
   a) Description and Characteristics:

The magnetic shielding is based on the physical principle of magnetisation/demagnetisation known as the “Hysteresis Cycle”; but specifically in the part of the curve in which the ferromagnetic materials are magnetised.

What one wants to achieve is to “line” the walls of the ‘SMART SHELTER’ with a material of high magnetic permeability (SIFE, MuMetal, ...) so that the lines of magnetic field coming from the emitting source are ‘absorbed’ in this lining and do not penetrate in the interior of the ‘SMART SHELTER’, protecting in this way the persons/equipment located therein.

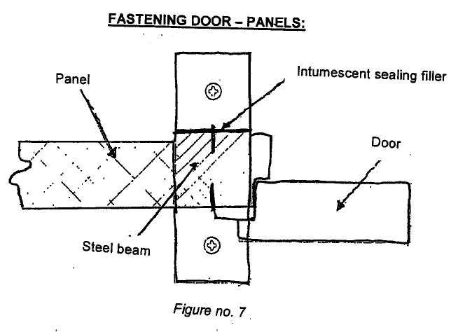

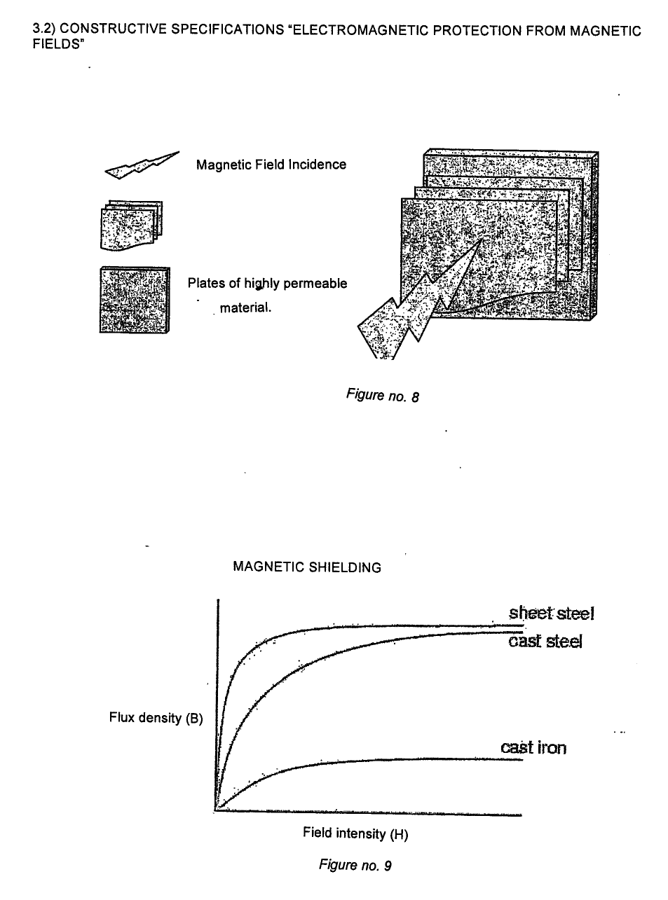

As can be seen in the FIG. 9 “MAGNETIC SHIELDING” (in Drawings), from a certain intensity of field (H) one arrives at a point (‘Saturation Bend’) from which regardless of how elevated is H, the density of flow (B) that crosses the ferromagnetic material (number of magnetic field lines that cross the material) scarcely increases; we have reached a Saturation area of the materials.

For practical purposes, this means that if the Intensity of the Magnetic Field (H) is sufficiently elevated it is not enough to install a ferromagnetic material. This is due to the fact that when this reaches its saturation area, it can no longer absorb more field lines.

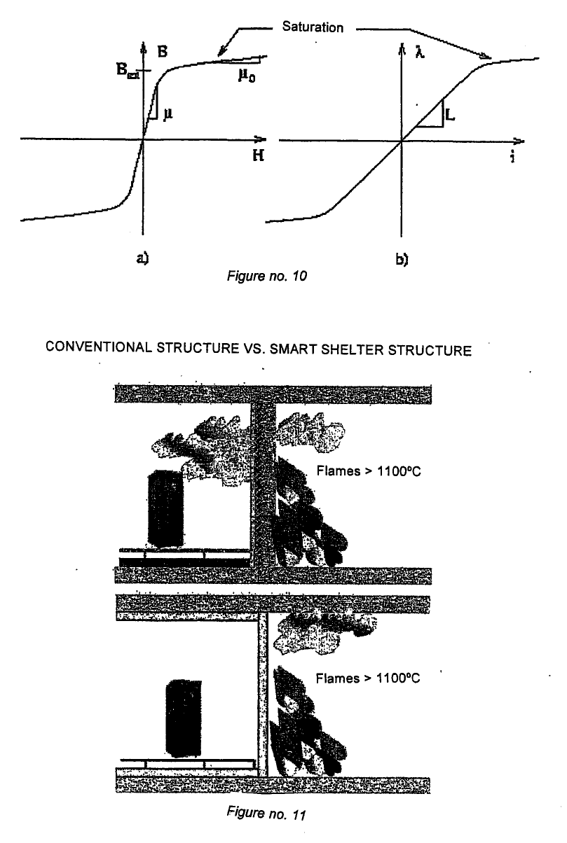

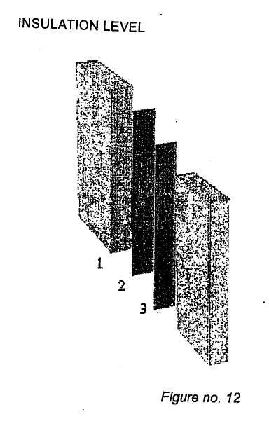

Also see FIG. 11 of ‘CONVENTIONAL STRUCTURE VS SMART SHELTER STRUCTURE’ in Drawings.

See Formulas of application in AST-Formula 2:

FORMULA 2

Applied formulas:

$${μ}_{r} = \frac{μ}{{μ}_{0}} ; μ = \frac{B}{H} ;$$

B=μH; =B A;
Where μ₀4=10⁷
(μ depends on each ferromagnetic material)

This (saturation of ferromagnetic materials) and many other problems have been resolved, obtaining some highly satisfactory results in different installations.

The process followed in providing effective shielding is the following:

First: The perimeter of the ‘SMART SHELTER’ is covered with plates of ferromagnetic material. The number of layers to install varies (between 1 and 8 layers, 0.5 mm thick) according to the characteristics of the location (distance to the emitting source, strength of the emitting source,...). The material used is silicon steel SIFE (Iron - Silicon Alloy with high permeability and elevated saturation point) of the following magnetic characteristics:

Composition (%)

Fe1-97

Si-3

Permeability (20 Gauss)

1,500

Maximum permeability

30,000

Saturation flow density

20,000

Second: As mentioned above, all ferromagnetic material reaches a point in which it is saturated and cannot absorb more flow from the field.

Thanks to the exclusive shielding technology used in the ‘SMART SHELTER’, it uses a final layer of Aluminium that is located in the entire perimeter to protect. This layer guarantees that the residual flow that the first layers of SIFE cannot absorb does not penetrate the shield. This occurs because the aluminium is a para-magnetic material of very high susceptibility (7.7-109 m3/kg; the susceptibility is the electrical equivalent to resistance, the more susceptibility a material has, the more difficult it is that it becomes magnetised). This last layer functions as a type of shield, not allowing passage of the residual flow that the SIFE had not been able to absorb.

Third: In order to guarantee to a greater extent the effectiveness of the shielding, both layers are welded (SIFE, Aluminium). This welding ‘covers' possible spaces and weak points of the structure.

Argon is used as the gas and a cord of higher-quality aluminium (purity, A199.999%) than that used in the previous layer is welded.

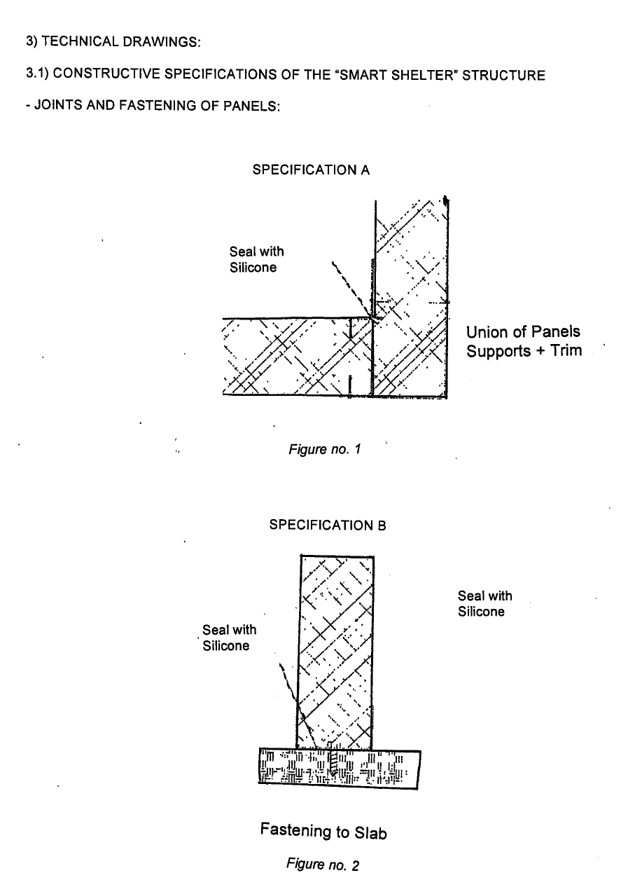

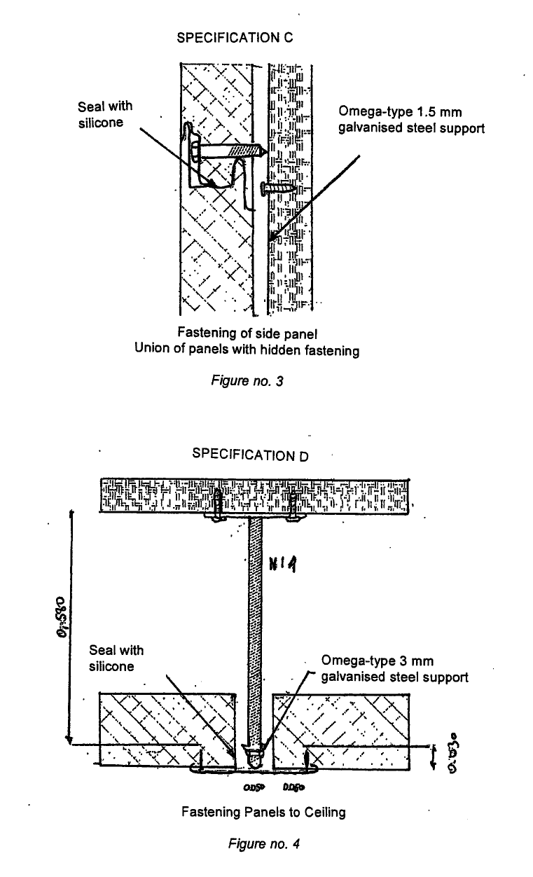

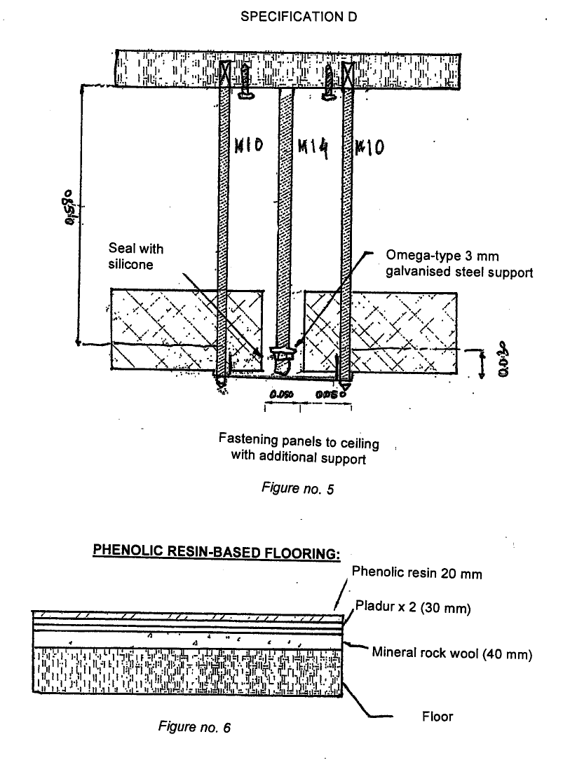

See FIG. 8 ‘CONSTRUCTIVE SPECIFICATIONS OF ELECTROMAGNETIC PROTECTION. MAGNETIC FIELDS’ in Drawings.

NOTE: The first layer of SIFE is always applied on the face most exposed to the magnetic field source.

a) Advantages:

As already mentioned, according to the latest version of the EMC/CEM regulation (Electro- Magnetic Compatibility / Compatibilidad Electro-Magnetica) applicable to l.T., scientific and critical environment equipment, the magnetic field levels that must be met are of 37.5 mG, in order to ensure its correct functioning (IEC 61000-4-8).

With this type of assembly (SIFE - Aluminium) shielding is achieved of up to 35 dB; reducing the field levels to under the 10 mG (security limit recommended by AST).

Being under the 10 mG assures a more correct operation for the equipment installed inside the ‘SMART SHELTER’ as well as a healthy work environment for the persons working therein.

1. Structural Panel:

As mentioned above, the ‘SMART SHELTER’ is an alterative to the more traditional methods of construction.

Traditionally the rooms dedicated to data storage were enclosed with concrete walls. This system presents the following disadvantages:
Although a 150-cm thick wall offers good performance regarding resistance to fire, its thermal stability is not as good as one would wish.
This type of construction involves a higher cost, execution time (drying of materials .... ), a larger number of workers, generation of dirt (powder, residue,...).
Concrete needs finishing work (paint, ...)
Concrete, by being porous, contains a high level of water. If the concrete wall is exposed to high temperatures, small drops of water, moisture, ... can appear through condensation in the interior of the protected room, with the consequent risk of short circuits.

Alternatively, enclosing the room with the exclusive technology of the ‘SMART SHELTER’ presents the following advantages:
Rapid and easy assembly (lighter materials and easy to install).
Cleaning.
Different types of finishes.
Greatstructural rigidity.
Modularity.
High resistance to fire.

See FIG. 11 ‘CONVENTIONAL STRUCTURE VS. SMART SHELTER STRUCTURE’ in Drawings.

All these advantages are obtained thanks to the special type of panel used for its construction.

a) Description and Characteristics of Panel:

It consists of a panel formed by two layers of galvanized steel (80% of ferrite) with a thickness of 1 mm, of variable exterior size (as needed, from 1.1 m in width up to 12 m in breadth). The outside part comes from the factory lacquered on the exterior part in either white or metallic grey. This panel comes filled with a fireproof mineral fibre pressed at 20 Tn (achieving a density of 145 kg/m³) and stratified until it forms a compact mass 100 mm thick.

The ends of each panel come finished in the shape of a ‘U’, forming a “male-female” system that fit together through pressure upon alternatively assembling each of the panels that make up the general structure.

The weight of each panel varies according to its thickness, this being around 23 kg/m² for 100 mm (standard thickness for obtaining an RF120). According to this, different RF's can be obtained (see table below):

| Thickness (mm) | Weight (kg/m2) | RF (min) |
|---|---|---|
| 50 | 15.8 | 30 |
| 80 | 20.2 | 60 |
| 100 | 23.1 | 120 |
| 150 | 30.3 | >120 |
| 200 | 37.6 | 180 |

For joining the panels, ‘male-female’ joints for a perfect seal of the joint.

Compressed and stratified mineral rock wool (density 145 gk/m³).

Galvanised steel sheets.

Fire resistance of the panel: As mentioned above, one of the principal advantages of these panels is their tremendous performance against fire. For a given thickness of 100 mm, they guarantee a RF120 (120 minutes of fire resistance) according to EN/UNE 23802. The panels also comply with the DIN 4102 standard that establishes a maximum temperature inside the room below 200° C. As an additional measure, in each and every one of the joints between panels, an intumescent material is applied (which increases its volume in the presence of heat). This material, of a density of 1,400 g/dm³ and reaction to fire Ml offers a passive resistance to fire of up to 120 minutes (RF 120), this intumescent filler has been tested in official laboratories according to the UNE 23.093-81 standard.

Watertight integrity: Thanks to the zero-capillarity of the mineral rock wool of which the panels are comprised, together with the special form of joining them (male-female); a high level of watertight integrity is assured, thus avoiding problems caused by floods.

a) Principal Advantages:

Finally, and in summary, the principal advantages that the ‘SMART SHELTER’ solution contributes regarding structural panelling are:
i. Speed/ease/modularity in installation
ii. Great structural rigidity
iii. Great resistance to fire (according to EN/UNE 23802). It includes:
a. Stability to fire
b. Low reaction to fire
c. No emission of inflammable gases
d. High level of thermal resistance
iv. High level of acoustic resistance (NBE CPA-96)
v. Very low moisture/weight ratio at <0.60% (it avoids appearance of drops from condensation in case of fire, thus impeding possible short circuits,...).

1. Joints and Seals of Panels:

Thanks to its exclusive sealing system, the ‘SMART SHELTER’ achieves very high levels of watertight integrity (IP67).

a) Description and Characteristics:

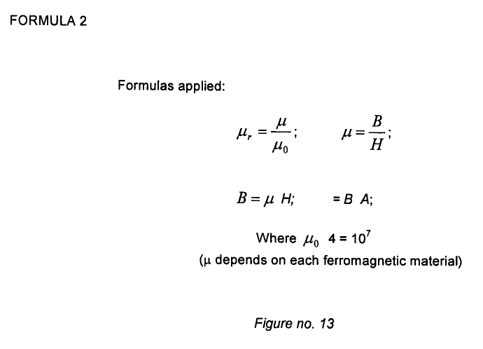

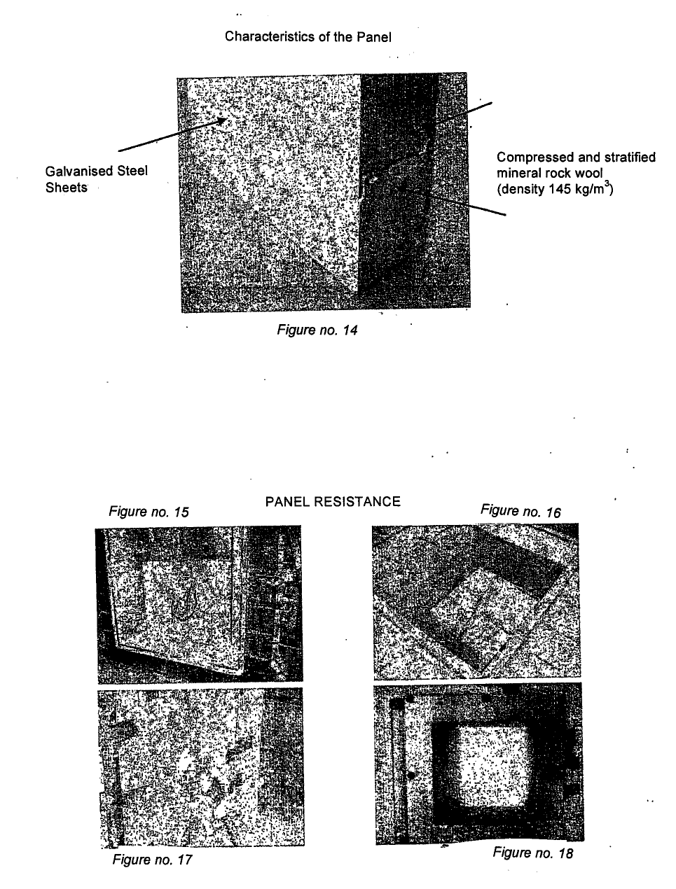

In order to achieve such a level of insulation, you do the following, See FIG. 12 in ‘INSULATION LEVEL’ in Drawings:

1. Prior to mechanical anchoring of the panels, you first join them with silicone (2), this special silicone (fireproof and waterproof, resistant to corrosion and dust resistant) guarantees the watertight integrity of the room against water and air/smoke (also offering an additional protection from fire).

2. Then a second layer of intumescent filler (3) (of the same type described above) in the outside part of the joint in order to guarantee appropriate protection against fire as well as to guarantee to a greater extent the watertight integrity of the room.

3. To finish, the thirdjoint is a strip (profile) of lacquered and riveted aluminium 1.5 mm thick that covers the union of the two panels, giving the structure greater structural rigidity and a quality finish (this last strip is also applied with silicone). (1) Mineral rock wool

b) Advantages:

This joint system is clean, more economic than other sealing methods, easy to apply and it guarantees total watertight integrity, preserving the fire resistance of the joints in the two following ways:

1. The intumescent filler increases in volume in presence of heat, completely sealing the joint.

2. Not letting air pass between the joints.

2. Phenolic Resin-Base Flooring:

In order to ensure a correct performance regarding the protection against fire and water, AST has developed a type of special modular flooring of easy installation.

a) Description and characteristics:

This flooring consists of a double 92-mm layer comprised of:

1. Layer of compressed and stratified natural mineral fibres with density of 150 kg/m³ (40 mm) x2.

2. A second 12-mm thick layer formed by two layers of MDF-type phenolic resin (Ml to Not inflammable) of great resistance to distortion in traction (0.65 N/mm2) as well as in flexing 27 N/mm2 ) and density 830 kg/m3 (see attached table).

The entire flooring (the joints) is sealed appropriately with fireproof and watertight silicone.

This flooring group provides great mechanical solidity, resistance to distortion and protection against fire and moisture.

b) Principal Advantacles:

This exclusive flooring used in the ‘SMART SHELTER’ offers the following advantages with respect to other more conventional solutions:
i. Easy installation
ii. Great structural rigidity
iii. Solid and compact base
iv. Fire protection
v. Total watertight integrity
vi. Reusable
vii. Modular, different thicknesses according to the number of layers (MDF, rock wool) according to customer's needs/specifications.
More economical.

3. APPLICATION: Data storage rooms:

As mentioned above in this document, the ‘SMART SHELTER’ solution has been developed specifically for data storage rooms (Servers, Racks, Patch Panels, Storage of magnetic tapes, ...). including and integrating:
Modular structural solution
ii. Heating/cooling
iii. Fire detection/extinction
iv. Flooring
v. Access control, CTV
vi. Alarm management (24x7)
   a) Principal Advanta-ges:

Below is presented a list of the principal advantages of the ‘SMART SHELTER’:

1. The ‘SMART SHELTER’ has been specifically developed for data storage rooms.

2. It is a perfectly analysed system that includes all that is mentioned above.
iii. It has been successfully installed previously in other installations.
iv. It is a turn-key installation.
v. Dedicated project management carried out by highly qualified personnel.
vi. A single person in charge of the entire project.
vii. Certificate of conformity according to the application standards.

1. AST, in relation to its fireproof, watertight and high-security enclosure called ‘SMART SHELTER’, claims the following:
2.1) Thanks to its special sealing/fastening system of the joints and/or unions that form the structure, an exceptional performance against fire is attained (see section 1) Technical Description of the Invention).
2.2) Thanks to the type of modular and fireproof flooring of its own design that complements the structure of the ‘SMART SHELTER’, the entire room is made watertight.
2.3) Its own technology regarding the shielding from electromagnetic field of both high and low frequencies, as well as its special form of integration with the rest of the ‘SMART SHELTER’ structure
